(19) United States
(12) Patent Application Publication
(10) Pub. No.: US 2022/0312629 A1
(43) Pub. Date: Sep. 29, 2022

(54) DC-DC Converter and Housing Therefor

(71) Applicants: HELLA GmbH & Co. KGaA, Lippstadt (DE); HDO Druckguß- und Oberflächentechnik GmbH, Paderborn (DE)

(72) Inventors: Jörg BERNS, Hemer (DE); Fred APEL, Bad Arolsen (DE)

(21) Appl. No.: 17/842,474

(22) Filed: Jun. 16, 2022

Related U.S. Application Data
(63) Continuation of application No. PCT/EP2020/086263, filed on Dec. 15, 2020.

(30) Foreign Application Priority Data
Dec. 16, 2019 (DE) 102019134565.0

(51) Int. Cl. H05K 7/20; H05K 5/04; H02M 7/00

(52) U.S. Cl. CPC H05K 7/209; H05K 5/04; H05K 7/2039; H02M 7/003

(57) ABSTRACT

A housing for a DC/DC power converter includes a cast metal part and a conduit part providing a conduit for a heat carrier medium. The conduit part includes a plastic part and a metal plate.

### CROSS REFERENCE TO RELATED APPLICATIONS

This application is a continuation of International Application No. PCT/EP2020/086263, filed on Dec. 15, 2020, which claims priority under 35 U.S.C. § 119 to Application No. DE 102019134565.0 filed on Dec. 16, 2019, the entire contents of which are hereby incorporated by reference.

### TECHNICAL FIELD

The disclosure relates to a housing for a power converter, in particular a direct current converter, for example a DC/DC converter with which a first voltage can be converted into a second voltage, having a cast metal part and at least one conduit for a heat carrier medium. The disclosure further relates to a power converter with such a housing and a method for producing such a housing.

### BACKGROUND

From DE 10 2016 119 303 A1, there is known a housing with an aluminum diecast part and a conduit made of a steel pipe. The conduit is surrounded by the aluminum diecast part. This is achieved in that the steel pipe is arranged as an insert in a casting mold for producing the aluminum diecast part before the mold is filled with the liquid aluminum.

The power converter housing known from DE 10 2016 119 303 A1 has the advantage that heat which arises during the operation of power semiconductor components of the power converter is absorbed by the cast metal part of the housing and can be effectively conducted away via a heat carrier medium flowing in the conduit. For this purpose, the conduit is fed through the cast metal part as far as possible at a site which lies close to one of the power semiconductor components in which the heat arises during operation of the power converter.

However, a disadvantage of the structure of the housing is that only very complex branches or junctions can be provided in the conduit in order to produce a conduit system via which the heat carrier medium can be fed simultaneously to different sites of the housing. So that the heat carrier medium can be conducted simultaneously to different sites of the housing, the conduit must have branches and junctions, or a plurality of conduits must be guided through the cast metal part, which are then brought together outside the cast metal part. The production of connections between the conduits made of steel pipes, whether inside or outside the cast metal part, is complex and costly. There is therefore a need for a housing with which it is possible to guide a heat carrier medium though the housing in a simultaneous and economical manner.

### SUMMARY

This object is achieved according to the disclosed structure in that the conduit is formed by a conduit part which has a plastic part and a metal plate. The plastic part can be a plastic injection molded part. The metal plate can be a sheet metal part. At least one part of the conduit can be provided in the plastic part. This part is an incomplete conduit part which is not capable of conducting a heat carrier medium. The metal plate can complete this at least one part of the conduit to a conduit in which the heat carrier medium can flow.

The heat carrier medium can be a coolant, in particular water.

From the document EP 3 216 544 A1, it is known to produce a water outlet fitting from the combination of a cast metal part and a plastic part. The water-conducting part is the plastic part, which is enclosed by the cast metal part. The plastic of the plastic part is a poor heat conductor which poorly absorbs heat from the water conducted by the fitting. In a water outlet fitting, this has the result that the water holds its temperature and does not heat the cast metal part of the fitting. A production of a housing according to the pattern of the water-conducting fitting would have the result that the heat cannot be conducted away via the housing from the interior of the housing. Transferring the technical teaching known from EP 3 216 544 A1 to a housing for a power converter would therefore not lead to an improvement of the heat transport as compared with the housing known from DE 10 2016 119 303 A1, but rather a worsening of the heat transport. EP 3 216 544 A1 therefore does not offer any suggestion to a person skilled in the art for the completion of the disclosed structure.

It is possible that the plastic part has at least one channel and the metal plate forms a cover with which the channel is covered. The channel covered with the cover can then form the at least one conduit. The channels can easily be produced in the plastic part during production. If the part is a plastic injection molded part, the channels can be provided as a negative in the injection mold. This can be useful if the conduit part is produced in large numbers. If a conduit part is to be produced in small numbers or even only as a single item, the conduit or the conduits can be produced in a plastic body by milling.

The metal plate used as a cover can be produced by punching, sawing, shearing, laser cutting or another suitable separating method from a metal sheet. It is not necessary for a metal plate used as a cover to have protruding or set back structures. There is also no need for holes in the metal plate. The metal plate can therefore be produced in a simple manner.

The plastic part can have a plurality of channels. Each channel can have branches and/or junctions via which the channels can be connected to one another. By this mechanism, it is possible to create complex conduits in the conduit part with which the heat carrier medium can be fed simultaneously to different sites in the housing in order to conduct heat away from these sites. The heat carrier medium can be guided to these sites without having previously been guided via other sites of the housing and having already absorbed heat there, whereby the ability to absorb heat would already have been reduced due to a temperature rise in the heat carrier medium.

The plastic part of a housing according to the disclosure can have at least one reservoir into which one or more channels empty or at which one or more channels begin. This reservoir can be covered by the cover. The reservoir which is covered by the cover can form a chamber which is connected to the at least one conduit. This chamber can be provided at a site of the housing at which a cooling load is required over a large area.

The conduit can have an inlet and an outlet via which the conduit can be connected to a feed line for the heat carrier medium and a return line for the heat carrier medium. For this purpose, connecting structures can be provided, in particular in the plastic part of the conduit part, which serve as a connection between the conduit part and the feed line and/or return line. A connecting structure of this type can be, for example, a threaded bore which is connected to the channel or one of the channels in the plastic part.

A housing of this type can be part of a power converter and, in particular, can accommodate power electronics components of a power converter, in particular the power semiconductor components. The components are protected by the housing against environmental influences such as moisture, dust, and dirt. The components of the power converter can thus be encapsulated in relation to the environment. At the same time, with the housing of the power converter, it is possible to effectively conduct away heat generated during operation of the power converter. The power converter can be a direct current converter, in particular a DC/DC converter with which a first voltage can be converted to a second voltage.

In order to produce a housing according to the invention, it is firstly necessary to produce the conduit part. For this, the plastic part and the metal plate must be produced and joined into the conduit part, wherein the metal plate covers the channels provided in the plastic part. The conduit part can then be placed as an insert into a casting mold which is then filled with a liquid metal, in particular aluminum or an aluminum alloy. After removal from the mold, the combination of the cast metal part and the conduit part can, if needed, be postprocessed to finish the production of the housing. It may be possible that no postprocessing is needed. The combination can be used off-tool after the usual deburring and cleaning.

### BRIEF DESCRIPTION OF THE DRAWINGS

The disclosed structure will now be described in greater detail making reference to the drawings.

FIG. 1 is a plastic part with channels provided therein.

FIG. 2 is a conduit part made of a plastic part and a metal plate.

FIG. 3 is a housing part comprising the conduit part and the cast metal part.

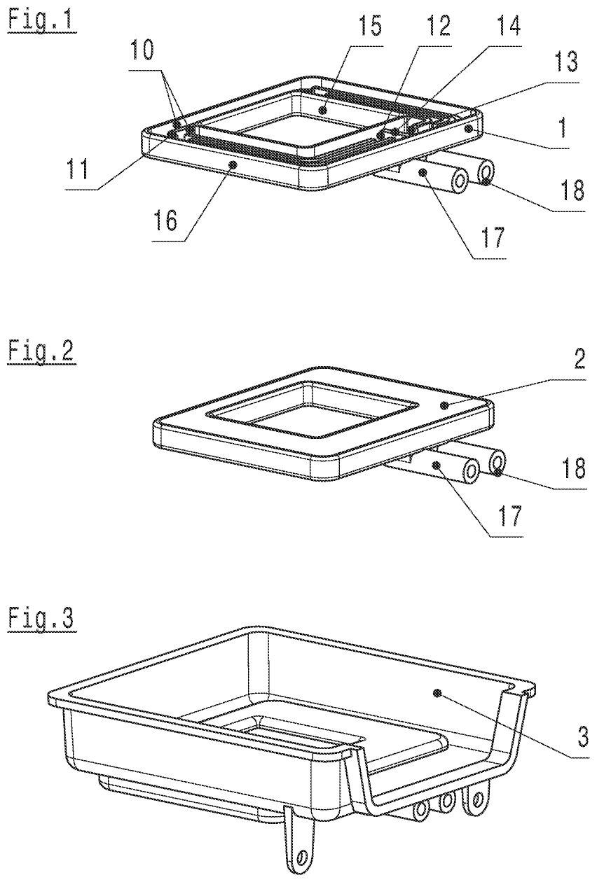

### DETAILED DESCRIPTION

The figures of the drawings show only one possible embodiment with an O-shaped cooling circuit. However, the invention makes possible any desired shape of the cooling circuit, provided a plastic part can be closed with a metal cover corresponding to the contour. This enables, for example, I-shaped, L-shaped, U-shaped and also wavelike and zigzag shapes, as well as a plurality of direction changes of the cooling circuit.

The plastic part 1 has the general shape of a rectangular frame. A plurality of channels 10 are formed into an upper side of this frame, the channels being separated from one another by webs 11 and being connected to one another by branches and junctions. The channels 10 form a channel system which has an inlet reservoir 12 and an outlet reservoir 13. The inlet reservoir 12 and the outlet reservoir 13 are separated from one another by a web 14.

The webs 11, 14 are somewhat drawn in relative to an inner side wall 15 and an outer side wall 16 of the plastic part, i.e., the webs 11, 14 are set back somewhat relative to the side walls 15, 16. This makes it possible to place a cover 2 on the webs 11, 14 in the region between the ends of the side walls. The cover 2 is a perforated, also frame-shaped metal plate which has been produced by punching from a metal sheet. The cover 2 covers the channels 10, the inlet reservoir 12 and the outlet reservoir 13. As a result, conduits are formed from the channels 10, and from the inlet reservoir, an inlet chamber and from the outlet reservoir an outlet chamber are formed.

The plastic part 1 has an inlet connecting piece 17 and an outlet connecting piece 18 to which a feed line and a return line can be connected. These connecting pieces 17, 18 are arranged on the underside of the frame. The inlet connecting piece 17 is connected to the inlet chamber and the outlet connecting piece 18 is connected to the outlet chamber.

The plastic part 1 and the cover 2 together form the conduit part that is arranged as an insert in a casting mold. The casting mold is then filled with liquid aluminum and the cast metal part 3 thereby cast is in a strong combination with the conduit part 1, 2. After removal from the mold and a possible postprocessing, this combination then forms the part of the housing according to the invention shown in FIG. 3.

What is claimed is:

1. A housing for a DC/DC power converter, comprising:
a cast metal part; and
a conduit part providing a conduit for a heat carrier medium, the conduit part comprising a plastic part and a metal plate.

2. The housing of claim 1, wherein the plastic part includes a plurality of channels having branches and/or junctions.

3. The housing of claim 1, wherein the plastic part includes a channel and the metal plate forms a cover with which the channel is covered, the channel forming the conduit.

4. The housing of claim 3, wherein the plastic part includes a reservoir into the channel empties or at which the channel begins.

5. The housing of claim 4, wherein the reservoir is covered by the cover and forms a chamber connected to the conduit.

6. The housing of claim 1, wherein the conduit has an inlet and an outlet via which the conduit is able to be connected to a feed line and a return line, respectively.

7. A DC/DC power converter, comprising:
a power semiconductor to convert a direct current; and
the housing of claim 1 in which the power semiconductor is arranged, wherein the conduit is arranged to convey a heat carrying medium to conduct away heat arising from the power semiconductor and transferring into the housing during operation of the power semiconductor.

8. A method for producing a DC/DC power converter, the method comprising:
producing a plastic part with a channel;
producing a metal plate;
joining the plastic part and the metal plate to form a conduit part such that the channel is covered by the metal plate;
inserting the conduit part into a casting mold as a casting core;
casting a cast metal part; and
removing the combination of the cast metal part and the conduit part from the mold.
